(19) United States
(12) Patent Application Publication
(10) Pub. No.: US 2024/0100634 A1
(43) Pub. Date: Mar. 28, 2024

(54) LEAD-FREE SOLDER ALLOY COMPOSITION, SOLDER BALL INCLUDING THE SAME, SOLDER PASTE INCLUDING THE LEAD-FREE SOLDER ALLOY COMPOSITION, SEMICONDUCTOR DEVICE INCLUDING HYBRID BONDING STRUCTURE INCLUDING THE LEAD-FREE SOLDER ALLOY COMPOSITION, AND METHOD OF MANUFACTURING SOLDER PASTE INCLUDING THE LEAD-FREE SOLDER ALLOY COMPOSITION

(71) Applicant: SAMSUNG ELECTRONICS CO., LTD., Suwon-si (KR)

(72) Inventors: Jaeseok JANG, Suwon-si, Gyeonggi-do (KR); Seunghyun BAIK, Suwon-si, Gyeonggi-do (KR)

(73) Assignee: Research & Business Foundation Sungkyunkwan University, Suwon-si (KR)

(21) Appl. No.: 18/370,016

(22) Filed: Sep. 19, 2023

(30) Foreign Application Priority Data
Sep. 28, 2022 (KR) 10-2022-0123648

(51) Int. Cl. B23K 35/02; B22F 1/054; B22F 1/142; B23K 35/26; C22C 12/00; C22C 13/00; C22F 1/16; C22F 3/00; H01L 23/00

(52) U.S. Cl. CPC B23K 35/025; B22F 1/0553; B22F 1/056; B22F 1/142; B23K 35/0244; B23K 35/262; B23K 35/264; C22C 12/00; C22C 13/00; C22F 1/16; C22F 3/00; H01L 24/13; H01L 24/16; H01L 24/81; B22F 2202/01; B22F 2304/058; B23K 2101/40

(57) ABSTRACT

A lead-free solder alloy composition includes a lead-free solder alloy; and a flower-shaped metal nano-particle including a metal core and protrusion portions extending from a surface of the metal core, wherein the metal core and the protrusion portions of the metal nano-particle include only one metal element.

### CROSS-REFERENCE TO RELATED APPLICATION

This application is based on and claims priority under 35 U.S.C. § 119 to Korean Patent Application No. 10-2022-0123648, filed on Sep. 28, 2022, in the Korean Intellectual Property Office, the disclosure of which is incorporated by reference herein in its entirety.

### BACKGROUND

### 1. Field

Embodiments relate to a lead-free solder alloy composition, a solder ball including the same, a solder paste including the lead-free solder alloy composition, a semiconductor device including a hybrid bonding structure including the lead-free solder alloy composition, and a method of manufacturing a solder paste including the lead-free solder alloy composition.

### 2. Description of the Related Art

Recently, as the electronics industry advances and the demands of consumers increase, the small size and high performance of semiconductor devices have been considered.

### SUMMARY

The embodiments may be realized by providing a lead-free solder alloy composition including a lead-free solder alloy; and a flower-shaped metal nano-particle including a metal core and protrusion portions extending from a surface of the metal core, wherein the metal core and the protrusion portions of the metal nano-particle include only one metal element.

The embodiments may be realized by providing a solder paste including the lead-free solder alloy composition according to an embodiment.

The embodiments may be realized by providing a solder ball including the lead-free solder alloy composition according to an embodiment.

The embodiments may be realized by providing a method of manufacturing a solder paste, the method including immersing a lead-free solder alloy and a metal nano-particle in a hexane solution; mixing the lead-free solder alloy with the metal nano-particle by performing an ultrasonic processing; removing the hexane solution by performing a thermal treatment; and mixing a flux with the lead-free solder alloy and the metal nano-particle after performing the ultrasonic processing, wherein the metal nano-particle includes a flower-shaped metal nano-particle including a metal core and protrusion portions extending from a surface of the metal core, and the metal core and the protrusion portions include only one metal element.

The embodiments may be realized by providing a semiconductor device including a printed circuit board (PCB); a semiconductor part; and a hybrid bonding structure between the PCB and the semiconductor part, the hybrid bonding structure including a solder paste, wherein the solder paste includes a lead-free solder alloy composition, the lead-free solder alloy composition includes a lead-free solder alloy and a flower-shaped metal nano-particle including a metal core and protrusion portions extending from a surface of the metal core, and the metal core and the protrusion portions each include only one metal element.

### BRIEF DESCRIPTION OF THE DRAWINGS

Features will be apparent to those of skill in the art by describing in detail exemplary embodiments with reference to the attached drawings in which:

FIG. 1 is a diagram illustrating a lead-free solder alloy composition according to an embodiment;

FIGS. 2A to 2C are diagrams illustrating analysis results, based on energy dispersive spectroscopy (EDS), of a lead-free solder alloy composition according to an embodiment and a comparative lead-free solder alloy composition;

FIGS. 3A and 3B are diagrams illustrating shapes after a soldering process is performed on a solder paste including a lead-free solder alloy composition and a solder ball;

FIG. 4 is a graph showing a result obtained by measuring a flexural modulus of each of a lead-free solder alloy composition according to an embodiment and a comparative lead-free solder alloy composition;

FIG. 5 is a graph showing a result obtained by measuring strain based on a stress of each of a lead-free solder alloy composition according to an embodiment and a comparative lead-free solder alloy composition;

FIG. 6 is a graph showing a result obtained by measuring a shear modulus, an ultimate tensile strength (UTS), a rigidity, and a toughness of each of a lead-free solder alloy composition according to an embodiment and a comparative lead-free solder alloy composition;

FIG. 7 is a flowchart illustrating a method of manufacturing a solder paste including a lead-free solder alloy composition, according to an embodiment; and

FIGS. 8A to 8E are cross-sectional views of stages in a method of manufacturing a semiconductor device including a hybrid bonding structure including a lead-free solder alloy composition, according to an embodiment.

### DETAILED DESCRIPTION

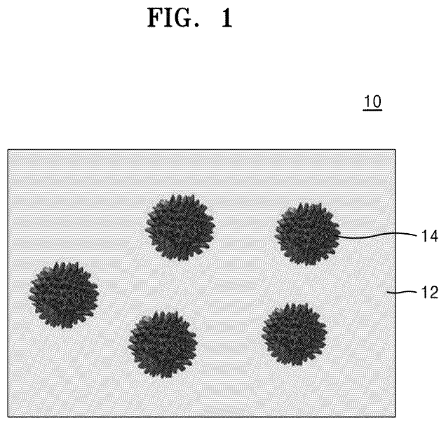

FIG. 1 is a diagram illustrating a lead-free solder alloy composition 10 according to an embodiment.

Referring to FIG. 1, in an embodiment, the lead-free solder alloy composition 10 may include a lead-free solder alloy 12 and a metal nano-particle 14. Here, lead free may denote that lead is not deliberately added, and a content of lead may be 0 or an inevitable impurity level.

The lead-free solder alloy 12 may be a lead-free solder alloy including tin (Sn). In an implementation, the lead-free solder alloy 12 may include, e.g., a tin-bismuth (Sn—Bi) alloy, a tin-bismuth-silver (Sn—Bi—Ag) alloy, or a tin-bismuth-indium (Sn—Bi—In) alloy. As used herein, the term “or” is not an exclusive term, e.g., “A or B” would include A, B, or A and B. In an implementation, when the lead-free solder alloy 12 is an Sn—Bi alloy, a wt % of Bi may be about 35 wt % to about 70 wt % and a wt % of Sn may be a remainder or balance amount, based on a total weight of the Sn—Bi. In an implementation, when the lead-free solder alloy 12 is a Sn—Bi—Ag alloy, a wt % of Bi may be about 35 wt % to about 75 wt %, a wt % of Ag may be about 0.1 wt % to about 20 wt %, and a wt % of Sn may be a remainder or balance amount, based on a total weight of the Sn—Bi—Ag. In an implementation, when the lead-free solder alloy 12 is an Sn—Bi—In alloy, a wt % of Bi may be about 15 wt % to about 65 wt %, a wt % of In may be about 5 wt % to about 75 wt %, and a wt % of Sn may be a remainder or balance amount, based on a total weight of the Sn—Bi—In.

The metal nano-particle 14 may be a flower-shaped metal nano-particle 14 including a metal core and protrusion portions extending from a surface of the metal core. In an implementation, the metal core and the protrusion portions may include only one metal element (e.g., may be a uniform, homogenous material consisting of a single metal element). In an implementation, the metal element may include silver (Ag), gold (Au), platinum (Pt), copper (Cu), or tungsten (W). In an implementation, the metal nano-particle 14 may be a flower-shaped metal nano-particle 14 that includes a metal core including only (e.g., consisting of) Ag and protrusion portions including only (e.g., consisting of) Ag and extending from the surface of the metal core. In an implementation, the metal nano-particle 14 may be included in the composition in an amount of, e.g., about 0.1 wt % to about 2.0 wt %, about 0.4 wt % to about 1.5 wt %, or about 1.0 wt % to about 1.5 wt %, based on a total weight of the lead-free solder alloy composition 10. In an implementation, the metal nano-particle 14 may be included in an amount of about 1.0 wt %, based on the total weight of the lead-free solder alloy composition 10. In an implementation, the metal core may have a spherical shape. In an implementation, a diameter of the metal core may be about 200 nm to about 500 nm. In an implementation, a length of each of the protrusion portions may be about 9 nm to about 22 nm. Here, a length of each of the protrusion portions may denote a length of each of the protrusion portions in a direction vertical to (e.g., outward from) the surface of the metal core. In an implementation, the protrusion portions may melt at about 100° C. or about 140° C. or about 120° C. to about 140° C. In an implementation, the protrusion portions may melt at about 140° C.

Some other lead-free solder alloy compositions may include metal nano-particles having a spherical shape. In this case, the metal nano-particles having a spherical shape may have a relatively high adhesion force, and the metal nano-particles may agglomerate in the other lead-free solder alloy compositions and may thus not be dispersed well. Due to this, in a case where a soldering process is performed on a solder paste including the other lead-free solder alloy compositions and a solder ball, Ag₃Sn formed by the soldering process may not be dispersed well and may be coarsened. Therefore, the mechanical properties of a solder including the other lead-free solder alloy compositions may be reduced, and misalignment between the solder paste and the solder ball could occur when performing a soldering process. In an implementation, the lead-free solder alloy composition 10 according to an embodiment may include the flower-shaped metal nano-particles 14. In this case, the flower-shaped metal nano-particles 14 may include the protrusion portions, and the flower-shaped metal nano-particles 14 may have a relatively low adhesion force and thus may not readily agglomerate in the lead-free solder alloy composition 10 and instead may be dispersed well. In an implementation, in a case where a soldering process is performed on a solder paste including a solder ball and the lead-free solder alloy composition 10 according to an embodiment, Ag₃Sn formed by the soldering process may be dispersed well and formed. Accordingly, the mechanical properties of a solder may be improved, and misalignment between the solder paste and the solder ball may be prevented when performing a soldering process.

The lead-free solder alloy composition 10 described above may be provided in the form of a solder ball or a solder paste.

The solder paste may include about 3 wt % to about 25 wt % of a flux, with respect to all of the lead-free solder alloy composition 10 (e.g., based on a total weight of the solder paste). In an implementation, the flux may include, e.g., a RMA-type paste flux and may be liquid at room temperature.

A compound of the lead-free solder alloy composition 10 and the flux may form a paste phase at room temperature.

The solder ball may be about 50 μm to about 1,000 μm in diameter and may be provided by molding the lead-free solder alloy composition 10 in a spherical shape.

In an implementation, the lead-free solder alloy composition 10 may be provided as an arbitrary icon, e.g., a cream, a bar, or a wire.

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

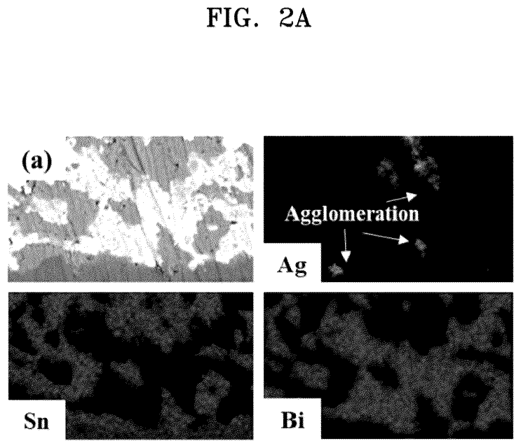

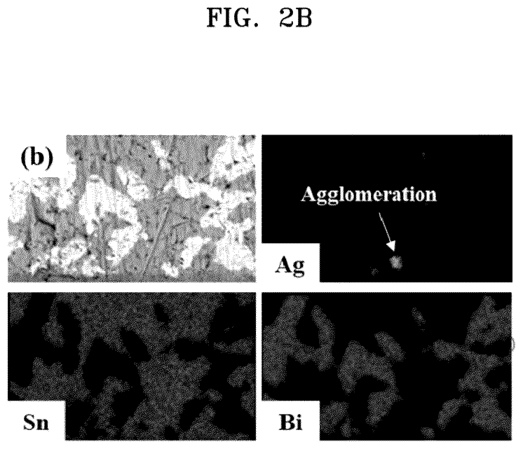

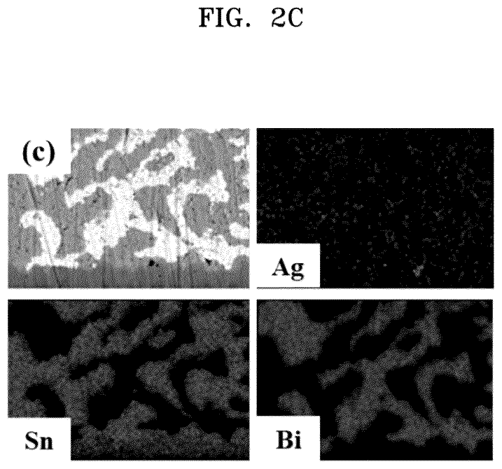

FIGS. 2A to 2C are diagrams illustrating analysis results, based on energy dispersive spectroscopy (EDS), of a lead-free solder alloy composition according to an embodiment and a comparative lead-free solder alloy composition. In detail, FIG. 2A is a diagram illustrating an analysis result, based on EDS, of a comparative lead-free solder alloy composition including no separate metal nano-particles, FIG. 2B is a diagram illustrating an analysis result, based on EDS, of a comparative lead-free solder alloy composition including metal nano-particles having a spherical shape, and FIG. 2C is a diagram illustrating an analysis result, based on EDS, of a lead-free solder alloy composition according to an embodiment. In FIGS. 2A to 2C, the lead-free solder alloy of the lead-free solder alloy composition was an Sn—Bi—Ag alloy, and a wt % of Bi was about 57.4 wt %, a wt % of Ag was about 0.4 wt %, and a wt % of Sn was a balance amount, with respect to total weight of Sn—Bi—Ag. Also, in FIGS. 2B and 2C, the metal nano-particle was a metal nano-particle including Ag.

Referring to FIG. 2A, in the comparative lead-free solder alloy composition including no separate metal nano-particles, it may be seen that Ag particles agglomerated and were not well dispersed in the comparative lead-free solder alloy composition.

Referring to FIG. 2B, in the comparative lead-free solder alloy composition including separate metal nano-particles having a spherical shape, it may be seen that Ag particles were relatively more dispersed than the comparative lead-free solder alloy composition including no separate metal nano-particles illustrated in FIG. 2A, but some Ag particles still agglomerated in the comparative lead-free solder alloy composition.

On the other hand, referring to FIG. 2C, in a lead-free solder alloy composition according to an embodiment, it may be seen that Ag particles did not agglomerate well, and were well dispersed in the lead-free solder alloy composition.

That is, referring to FIGS. 2A to 2C, it may be seen that Ag particles of the lead-free solder alloy composition according to an embodiment did not agglomerate well and were well dispersed, compared to the comparative lead-free solder alloy compositions.

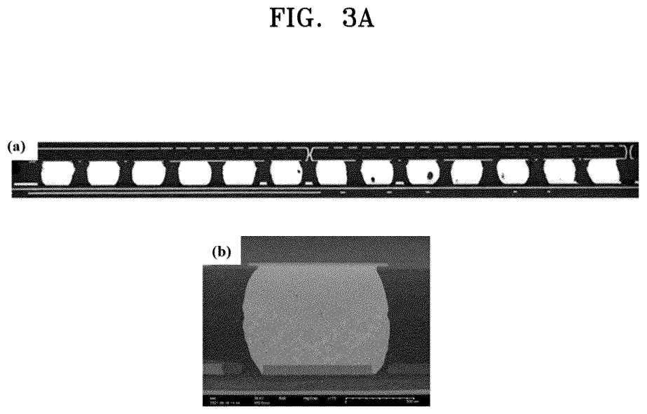

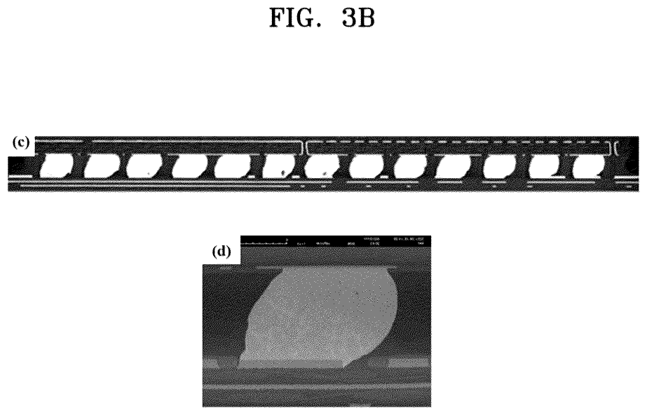

FIGS. 3A and 3B are diagrams illustrating shapes after a soldering process was performed on a solder paste including a lead-free solder alloy composition and a solder ball. In detail, FIG. 3A is a diagram illustrating a shape after a soldering process was performed on a solder paste including a lead-free solder alloy composition according to an embodiment and a solder ball, and FIG. 3B is a diagram illustrating a shape after a soldering process was performed on a solder paste including a comparative lead-free solder alloy composition and a solder ball, which include sphere-shaped metal nanoparticles, not flower-shaped metal nanoparticles. In FIGS. 3A and 3B, the solder ball was a solder ball including an Sn—Ag—Cu alloy, and the lead-free solder alloy of the lead-free solder alloy composition included in the solder paste was a lead-free solder alloy including an Sn—Bi alloy.

Referring to FIG. 3A, it may be seen that misalignment between a solder ball and a solder paste did not occur when a soldering process was performed on a solder paste including a lead-free solder alloy composition according to an embodiment and a solder ball.

On the other hand, referring to FIG. 3B, it may be seen that misalignment between a solder ball and a solder paste occurred when the soldering process was performed on a solder paste including the comparative lead-free solder alloy composition and a solder ball.

That is, referring to FIGS. 3A and 3B, in the solder paste including the lead-free solder alloy composition according to an embodiment and the solder ball, it may be seen that misalignment between a solder ball and a solder paste did not occur when a soldering process was performed on the solder paste and the solder ball.

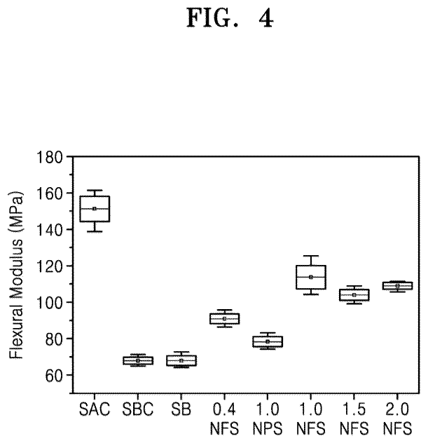

FIG. 4 and Table 1 show a result obtained by measuring a flexural modulus of each of a lead-free solder alloy composition according to an embodiment and a comparative lead-free solder alloy composition. Hereinafter, NPS may denote a lead-free solder alloy composition (i.e., a comparative lead-free solder alloy composition) including metal nano-particles having a spherical shape and a lead-free solder alloy including an Sn—Bi alloy, and NFS may denote a lead-free solder alloy composition (i.e., a lead-free solder alloy composition according to an embodiment) including metal nano-particles having a flower shape and a lead-free solder alloy including an Sn—Bi alloy. Also, in FIG. 4 and Table 1, the comparative lead-free solder alloy composition and the lead-free solder alloy composition according to an embodiment each included a lead-free solder alloy including an Sn-58Bi alloy. In FIG. 4 and Table 1, a flexural modulus was measured by a 3-point flexural test scheme.

TABLE 1

| | Average | Improvement |
|---|---|---|
| | (MPa) | Ratio (%) |
| Sn—3.0Ag—0.5Cu | 151.16 | — |
| Sn—57.6Bi—0.4Ag | 68.06 | — |
| Sn—58Bi | 68.15 | Ref. |
| 0.4 wt % NFS | 91.16 | 34%▴ |
| 1.0 wt % NPS | 78.26 | 15%▴ |
| 1.0 wt % NFS | 113.67 | 67%▴ |
| 1.5 wt % NPS | 80.13 | 18%▴ |
| 1.5 wt % NFS | 104.08 | 53%▴ |
| 2.0 wt % NPS | 79.85 | 17%▴ |
| 2.0 wt % NFS | 109.07 | 60%▴ |

Referring to FIG. 4 and Table 1, it may be seen that the flexural modulus of a lead-free solder alloy composition NFS according to an embodiment had a value which was greater than that of a flexural modulus of the comparative lead-free solder alloy composition NPS or that of a flexural modulus of a case (Sn-3.0Ag-0.5Cu, Sn-57.6Bi-0.4Ag, and Sn-58Bi) where metal nano-particles were not separately provided therein. That is, referring to FIG. 4 and Table 1, it may be seen that the lead-free solder alloy composition according to an embodiment had mechanical properties which were better than those of the comparative lead-free solder alloy composition.

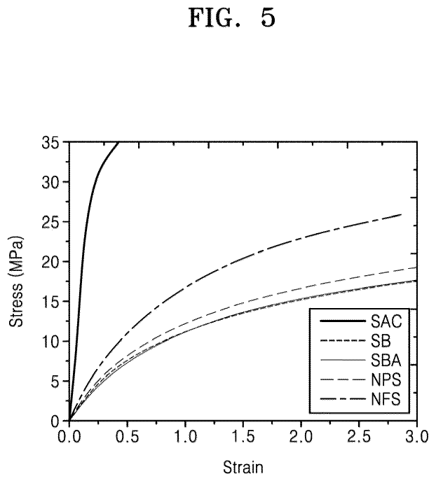

FIG. 5 and Table 2 show a result obtained by measuring strain based on stress of each of a lead-free solder alloy composition according to an embodiment and a comparative lead-free solder alloy composition. Referring to FIG. 5 and Table 2, a lead-free solder alloy composition NFS according to an embodiment included a flower-shaped metal nano-particle in an amount of 1.0 wt %, with respect to a total weight of the lead-free solder alloy composition, and the comparative lead-free solder alloy composition NPS included a sphere-shaped metal nano-particle in an amount of 1.0 wt %, with respect to the total weight of the comparative lead-free solder alloy composition. Also, in FIG. 5 and Table 2, strains of lead-free solder alloy compositions based on stress were measured based on a 3-point bending test scheme at about 100° C.

TABLE 2

| (Strain) | | 5 MPa | 10 MPa | 15 MPa | 20 MPa |
|---|---|---|---|---|---|
| Sn—3.0Ag—0.5Cu | | 0.03 | 0.06 | 0.09 | 0.11 |
| Sn—58Bi | | 0.29 | 0.83 | 1.94 | 4.89 |
| Sn—57.6Bi—0.4Ag | | 0.26 | 0.82 | 1.99 | 4.73 |
| NPS | | 0.25 | 0.70 | 1.56 | 3.47 |
| NFS | | 0.18 | 0.44 | 0.83 | 1.46 |
| Improvement | NFS vs | 38%▾ | 47%▾ | 57%▾ | 70%▾ |
| Ratio | Sn—58Bi | | | | |
| | NFS vs NPS | 28%▾ | 37%▾ | 47%▾ | 58%▾ |

Referring to FIG. 5 and Table 2, it may be seen that strain of the lead-free solder alloy composition NFS according to an embodiment had a value which was greater than that of strain of the comparative lead-free solder alloy composition NPS or that of strain of a case (Sn-3.0Ag-0.5Cu, Sn-57.6Bi-0.4Ag, and Sn-58Bi) where metal nano-particles were not separately provided therein. That is, referring to FIG. 5 and Table 2, it may be seen that the lead-free solder alloy composition according to an embodiment had mechanical properties that were better than those of the comparative lead-free solder alloy composition.

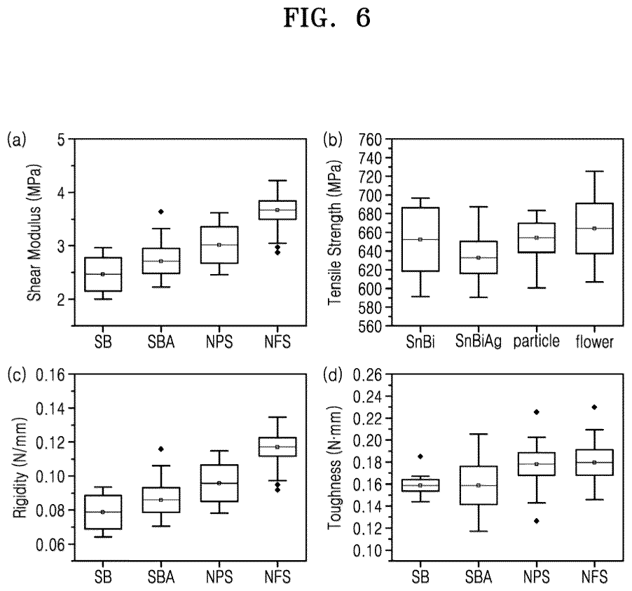

FIG. 6 and Table 3 show a result obtained by measuring a shear modulus, an ultimate tensile strength (UTS), a rigidity, and a toughness of each of a lead-free solder alloy composition according to an embodiment and a comparative lead-free solder alloy composition. In detail, in FIG. 6, part (a) is a graph showing a shear modulus, part (b) is a graph showing UTS, part (c) is a graph showing rigidity, and part (d) is a graph showing a result obtained by measuring toughness. In FIG. 6 and Table 3, the lead-free solder alloy composition NFS according to an embodiment included a flower-shaped metal nano-particle in an amount of 1.0 wt %, and the comparative lead-free solder alloy composition NPS included a sphere-shaped metal nano-particle in an amount of 1.0 wt %. Also, in FIG. 6 and Table 3, a shear modulus, UTS, rigidity, and toughness were measured based on a ball shear test scheme.

TABLE 3

| | | Shear | | | |
|---|---|---|---|---|---|
| | | Modulus | UTS | Rigidity | Toughness |
| | | (Mpa) | (Mpa) | (N/mm) | (N · mm) |
| Sn—58Bi | | 2.501 | 694.992 | 0.080 | 0.160 |
| Sa—57.6Bi—0.4Ag | | 2.765 | 704.927 | 0.088 | 0.161 |
| NPS | | 3.044 | 722.131 | 0.097 | 0.179 |
| NFS | | 3.627 | 741.136 | 0.116 | 0.182 |
| Improvement | NFS vs | 45.02%↑ | 6.64%↑ | 45.00%↑ | 13.75%↑ |
| Ratio | Sn—58Bi | | | | |
| | NFS vs NPS | 19.15%↑ | 2.63%↑ | 19.59%↑ | 1.68%↑ |

Referring to FIG. 6 and Table 3, it may be seen that a shear modulus, UTS, rigidity, and toughness of the lead-free solder alloy composition NFS according to an embodiment had values which were greater than those of a shear modulus, UTS, rigidity, and toughness of the comparative lead-free solder alloy composition NPS or those of a shear modulus, UTS, rigidity, and toughness of a case (Sn-57.6Bi-0.4Ag and Sn-58Bi) where metal nano-particles were not separately provided therein. That is, referring to FIG. 6 and Table 3, it may be seen that the lead-free solder alloy composition according to an embodiment had mechanical properties which were better than those of the comparative lead-free solder alloy composition.

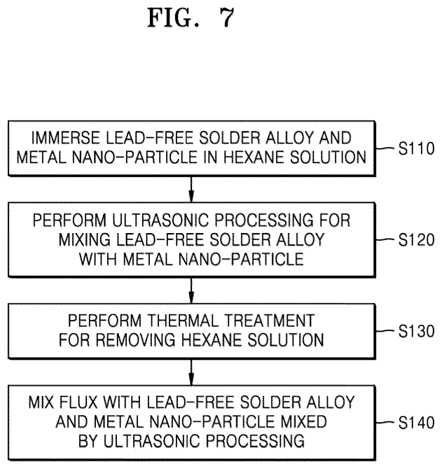

FIG. 7 is a flowchart illustrating a method of manufacturing a solder paste including a lead-free solder alloy composition, according to an embodiment.

Referring to FIG. 7, first, a lead-free solder alloy and metal nano-particles may be immersed in a hexane solution in operation S 110. The lead-free solder alloy may be, e.g., an Sn—Bi alloy. In an implementation, a wt % of Bi of the Sn—Bi alloy may be about 58 wt % and a wt % of Sn may be a balance amount, with respect to a total weight of the Sn—Bi alloy.

In an implementation, the metal nano-particle may be a flower-shaped metal nano-particle including a metal core and protrusion portions extending from a surface of the metal core. In an implementation, the metal core and the protrusion portions may include only Ag. In an implementation, a wt % of the metal nano-particle may be about 0.4 wt % to about 2.0 wt %, with respect to a total weight of the lead-free solder alloy composition. The metal nano-particle may be manufactured through the following process. First, a silver nitrate solution may be manufactured by adding silver nitrate to deionized water, an ammonium citrate dibasic solution may be manufactured by adding ammonium citrate dibasic to deionized water, and a boric acid solution may be manufactured by adding boric acid to deionized water. Subsequently, the silver nitrate solution, the ammonium citrate dibasic solution, and the boric acid solution may be heated to a temperature of about 50° C., and the solutions may be mixed. Subsequently, a mixed solution where the solutions are mixed may be stirred for about 2 sec at a temperature of about 50° C., and an ammonia solution may be added until the mixed solution is transparent. Subsequently, an L-ascorbic acid solution having the same concentration as that of the silver nitrate solution may be manufactured by adding L-ascorbic acid to deionized water, and then, the L-ascorbic acid solution may be added to the mixed solution to which the ammonia solution is added and the mixed solution to which the L-ascorbic acid is added may be stirred for about 30 min, thereby manufacturing the metal nano-particle. The mixed solution including the manufactured metal nano-particle may be vacuum-filtered, and then, by performing a cleaning process using deionized water, the metal nano-particle in a solid powder form may be obtained.

Subsequently, in order to mix metal nano-particles with a lead-free solder alloy immersed in the hexane solution, ultrasound or ultrasonic processing may be performed on the lead-free solder alloy and the metal nano-particles in operation S120. In an implementation, the ultrasonic processing may be performed by using tip-type ultrasound waves. In an implementation, the ultrasonic processing may be performed for, e.g., about 1 min to about 3 min. In an implementation, the ultrasonic processing may be performed, e.g., 6 times to 12 times or 8 times to 10 times. In an implementation, the ultrasonic processing may be performed 9 times, each time of the ultrasonic processing may be performed for about 2 min. In an implementation, the ultrasonic processing may be performed with intervals of about 5 sec to about 15 sec therebetween. In an implementation, the ultrasonic processing may be performed 9 times and with an interval of about 10 sec between each time the ultrasonic processing is performed.

Subsequently, in order to remove the hexane solution, thermal treatment may be performed on the hexane (in which the lead-free solder alloy has been mixed with the metal nano-particles) in operation S130. In an implementation, the thermal treatment may be performed at about 30° C. to about 50° C. In an implementation, the thermal treatment may be performed for about 15 min to about 25 min. In an implementation, the thermal treatment may be performed at a temperature of about 40° C. and may be performed for about 20 min. The hexane solution may be removed by the thermal treatment.

Finally, the lead-free solder alloy and the metal nano-particles (which have been mixed with each other) may be mixed with flux. In an implementation, the lead-free solder alloy and the metal nano-particles may be mixed with the flux using a Thinky mixer. In an implementation, the Thinky mixer may rotate for about 1 min at a rotational speed of about 1,000 rpm to mix the flux with the lead-free solder alloy and the metal nano-particles. As operation S140 is performed, a solder paste including the lead-free solder alloy composition according to an embodiment may be manufactured.

Other lead-free solder alloy compositions may include metal nano-particles having a spherical shape. In this case, the metal nano-particles having a spherical shape may have a relatively high adhesion force, and the metal nano-particles may agglomerate in the other lead-free solder alloy composition and may thus not be dispersed well. Due to this, if a soldering process were to be performed using a solder paste including the other lead-free solder alloy composition and a solder ball, Ag₃Sn formed by the soldering process may not be dispersed well and could be coarsened. Therefore, the mechanical properties of a solder including the other lead-free solder alloy composition may be reduced, and misalignment between the solder paste and the solder ball may occur when performing a soldering process. On the other hand, the lead-free solder alloy composition 10 according to an embodiment may include flower-shaped metal nano-particles. In this case, the flower-shaped metal nano-particles include protrusion portions, and the flower-shaped metal nano-particles may have a relatively low adhesion force and may thus may not agglomerate well in the lead-free solder alloy composition 10, and may be dispersed well. Therefore, in a case where a soldering process is performed using a solder paste including a solder ball and the lead-free solder alloy composition 10 according to an embodiment, Ag₃Sn formed by the soldering process may be dispersed well and formed. Accordingly, the mechanical properties of a solder may be improved, and misalignment between the solder paste and the solder ball may be prevented when performing a soldering process.

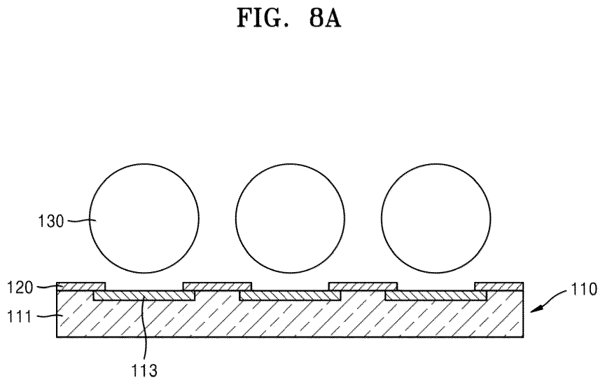

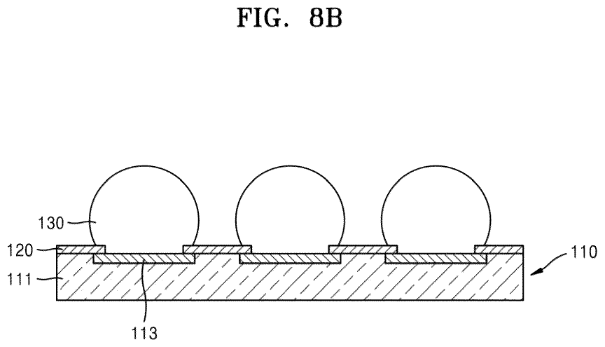

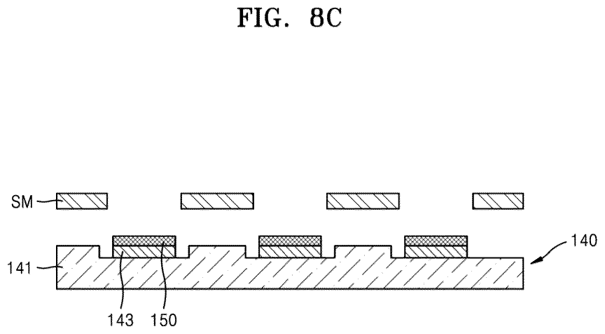

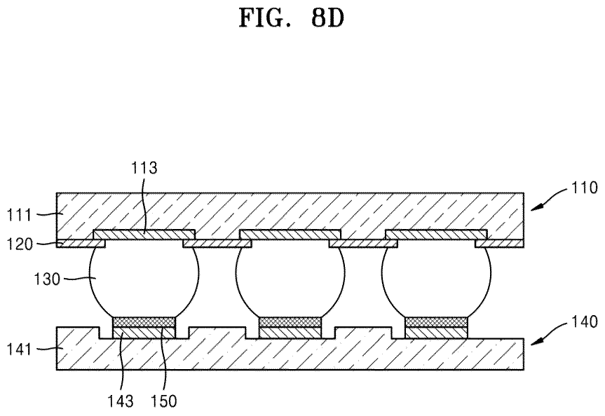

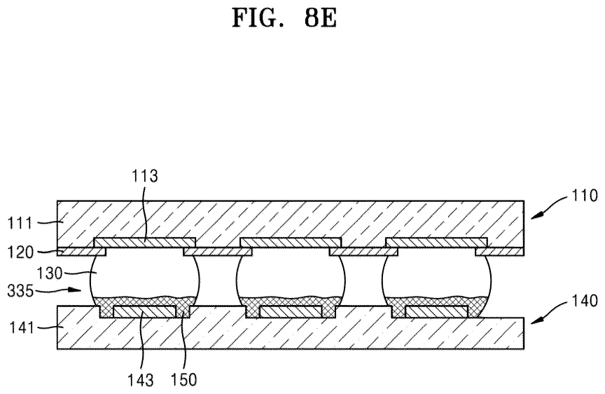

FIGS. 8A to 8E are cross-sectional views of stages in a method of manufacturing a semiconductor device including a hybrid bonding structure including a lead-free solder alloy composition, according to an embodiment.

Referring to FIG. 8, first, solder balls 130 may be arranged on a semiconductor part 111. The semiconductor part 111 may be a semiconductor chip, or may be a semiconductor package where at least one semiconductor chip is mounted on a package substrate and is covered by a molding layer. In an implementation, the semiconductor chip may be a memory chip or a logic chip. The memory chip may include, e.g., a volatile memory chip, such as dynamic random access memory (DRAM) or static random access memory (SRAM), or a non-volatile memory chip such as phase-change random access memory (PRAM), magnetoresistive random access memory (MRAM), ferroelectric random access memory (FeRAM), or resistive random access memory (RRAM). In an implementation, the logic chip may include, e.g., a microprocessor, an analog device, or a digital signal processor. In an implementation, the semiconductor package may include, e.g., a high bandwidth memory (HBM) package.

The semiconductor part 111 may include a plurality of first pads 113. The plurality of first pads 113 may be buried in the semiconductor part 111. In an implementation, an upper surface of each of the plurality of first pads 113 may be coplanar with an upper surface of the semiconductor part 111. A passivation layer 120 may be on the upper surface of the semiconductor part 111.

The solder balls 130 may be on the plurality of first pads 113 of the semiconductor part 111. In an implementation, the solder balls 130 may overlap the plurality of first pads 113 in a direction vertical to the upper surface of the semiconductor part 111.

Referring to FIG. 8B, in a resultant material of FIG. 8A, the solder balls 130 may be attached on the plurality of first pads 113. In an implementation, the solder balls 130 may each include, e.g., an Sn—Ag—Cu solder alloy, an Sn—Bi solder alloy, an Sn—Bi—Ag solder alloy, or an Sn—Ag—Cu—Ni solder alloy.

Referring to FIG. 8C, a solder paste 150 may be coated on a provided substrate 140 by using a mask SM. The substrate 140 may include a base board layer 141 and a second pad 143. The base board layer 141 may include, e.g., phenol resin, epoxy resin, or polyimide. In an implementation, the substrate 140 may include, e.g., a printed circuit board (PCB) or a flexible PCB (FPCB). The solder paste 150 may include a lead-free solder alloy composition according to an embodiment. In an implementation, the solder paste 150 may be coated by, e.g., a stencil printing process.

Referring to FIG. 8D, the solder balls 130 may be disposed to face the solder paste 150, and thus, the solder balls 130 may contact the solder paste 150.

Referring to FIG. 8E, in a resultant material of FIG. 8D, the solder paste 150 may be melted by performing a soldering process thereon, and the melted solder paste 150 may be bonded to the solder balls 130. A melting temperature of the solder paste 150 may be, e.g., about 140° C. or less. In an implementation, the melting temperature of the solder paste 150 may be, e.g., about 120° C. to about 140° C. The solder paste 150 melted by the soldering process may be bonded to the solder balls 130, and thus, a hybrid bonding structure 335 may be formed. Subsequently, by performing a cooling process, the hybrid bonding structure 335 formed through the soldering process may be cured. As the hybrid bonding structure 335 is formed, the semiconductor part 111 may be connected with the substrate 140, and thus, the semiconductor device 100 may be manufactured.

Some other lead-free solder alloy compositions may include metal nano-particles having a spherical shape. In this case, the metal nano-particles having a spherical shape may have a relatively high adhesion force, and the metal nano-particles may agglomerate in the other lead-free solder alloy compositions and may thus not be dispersed well. Due to this, in a case where a soldering process is performed on a solder paste including the other lead-free solder alloy compositions and a solder ball, Ag₃Sn formed by the soldering process may not be dispersed well and may be coarsened. Therefore, the mechanical properties of a solder including the other lead-free solder alloy compositions may be reduced, and misalignment between the solder paste and the solder ball could occur when performing a soldering process. On the other hand, the lead-free solder alloy composition 10 according to an embodiment may include the flower-shaped metal nano-particles. In this case, the flower-shaped metal nano-particles may include protrusion portions, and the flower-shaped metal nano-particles may have a relatively low adhesion force and may thus may not agglomerate well in the lead-free solder alloy composition 10 and may be dispersed well. Therefore, in a case where a soldering process is performed on a solder paste including a solder ball and the lead-free solder alloy composition 10 according to an embodiment, Ag₃Sn formed by the soldering process may be dispersed well and formed. Accordingly, the mechanical properties of a solder may be improved, and misalignment between the solder paste and the solder ball may be prevented when performing a soldering process. As a result, the mechanical properties of a plurality of hybrid bonding structures formed by performing a soldering process on the solder paste and the solder ball may be improved, and thus, the structure reliability of a semiconductor device including the hybrid bonding structures may be improved.

By way of summation and review, a plurality of semiconductor devices may be highly integrated and mounted on one substrate. In this case, in order to prevent a reduction in performance of a semiconductor device caused by thermal damage and the occurrence of a defect such as warpage of a semiconductor device, a solder alloy composition may facilitate mounting of a semiconductor device on a substrate at a low temperature.

One or more embodiments may provide a lead-free solder alloy composition including a lead-free solder alloy and a metal nano-particle.

One or more embodiments may provide a lead-free solder alloy composition having excellent mechanical properties.

One or more embodiments may provide a method of manufacturing a solder paste including a lead-free solder alloy composition having excellent mechanical properties.

One or more embodiments may provide a semiconductor device including a hybrid bonding structure formed by a solder paste including a lead-free solder alloy composition having excellent mechanical properties.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A lead-free solder alloy composition, comprising:
a lead-free solder alloy; and
a flower-shaped metal nano-particle including a metal core and protrusion portions extending from a surface of the metal core,
wherein the metal core and the protrusion portions of the metal nano-particle include only one metal element.

2. The lead-free solder alloy composition as claimed in claim 1, wherein the lead-free solder alloy includes a tin-bismuth (Sn—Bi) alloy, a tin-bismuth-silver (Sn—Bi—Ag) alloy, or a tin-bismuth-indium (Sn—Bi—In) alloy.

3. The lead-free solder alloy composition as claimed in claim 1, wherein the metal element of the metal nano-particle includes silver (Ag), gold (Au), platinum (Pt), copper (Cu), or tungsten (W).

4. The lead-free solder alloy composition as claimed in claim 1, wherein the protrusion portions melt at 120° C. to 140° C.

5. The lead-free solder alloy composition as claimed in claim 1, wherein a length of each of the protrusion portions is 9 nm to 22 nm.

6. The lead-free solder alloy composition as claimed in claim 1, wherein a diameter of the metal core is 200 nm to 500 nm.

7. The lead-free solder alloy composition as claimed in claim 1, wherein the metal nano-particle is included in the lead-free solder alloy composition in an amount of 0.1 wt % to 2.0 wt %, based on a total weight of the lead-free solder alloy composition.

8. A solder paste comprising the lead-free solder alloy composition as claimed in claim 1.

9. A solder ball comprising the lead-free solder alloy composition as claimed in claim 1.

10. A method of manufacturing a solder paste, the method comprising:
immersing a lead-free solder alloy and a metal nano-particle in a hexane solution;
mixing the lead-free solder alloy with the metal nano-particle by performing an ultrasonic processing;
removing the hexane solution by performing a thermal treatment; and
mixing a flux with the lead-free solder alloy and the metal nano-particle after performing the ultrasonic processing,
wherein:
the metal nano-particle includes a flower-shaped metal nano-particle including a metal core and protrusion portions extending from a surface of the metal core, and
the metal core and the protrusion portions include only one metal element.

11. The method as claimed in claim 10, wherein the lead-free solder alloy includes a tin-bismuth (Sn—Bi) alloy, a tin-bismuth-silver (Sn—Bi—Ag) alloy, or a tin-bismuth-indium (Sn—Bi—In) alloy.

12. The method as claimed in claim 10, wherein the metal element of the metal nano-particle includes silver (Ag), gold (Au), platinum (Pt), copper (Cu), or tungsten (W).

13. The method as claimed in claim 10, wherein, in the mixing of the lead-free solder alloy with the metal nano-particle, the metal nano-particle is included in an amount of 0.1 wt % to 2.0 wt %, based on a total weight of the metal nano-particle and the lead-free solder alloy.

14. The method as claimed in claim 10, wherein:
a length of each of the protrusion portions is 9 nm to 22 nm, and
a diameter of the metal core is 200 nm to 500 nm.

15. The method as claimed in claim 10, wherein:
the ultrasonic processing is performed for 1 min to 3 min, and
the ultrasonic processing is performed 8 times to 10 times with intervals of 5 sec to 15 sec between each time.

16. The method as claimed in claim 10, wherein:
the thermal treatment is performed at 30° C. to 50° C., and
the thermal treatment is performed for 15 min to 25 min.

17. A semiconductor device, comprising:
a printed circuit board (PCB);
a semiconductor part; and
a hybrid bonding structure between the PCB and the semiconductor part, the hybrid bonding structure including a solder paste,
wherein:
the solder paste includes a lead-free solder alloy composition,
the lead-free solder alloy composition includes a lead-free solder alloy and a flower-shaped metal nano-particle including a metal core and protrusion portions extending from a surface of the metal core, and
the metal core and the protrusion portions each include only one metal element.

18. The semiconductor device as claimed in claim 17, wherein the metal element of the metal nano-particle includes silver (Ag), gold (Au), platinum (Pt), copper (Cu), or tungsten (W).

19. The semiconductor device as claimed in claim 17, wherein the metal nano-particle is included in the lead-free solder alloy composition in an amount of 0.1 wt % to 2.0 wt %, based on a total weight of the lead-free solder alloy composition.

20. The semiconductor device as claimed in claim 17, wherein:
the hybrid bonding structure further includes a solder ball, and
the solder ball includes a tin-silver-copper (Sn—Ag—Cu) alloy.
